(19) United States
(12) Patent Application Publication
(10) Pub. No.: US 2022/0415553 A1
(43) Pub. Date: Dec. 29, 2022

(54) INDUCTOR DEVICE, FILTER DEVICE AND STEERING CONTROL DEVICE

(71) Applicant: MANDO Corporation, Pyeongtaek (KR)

(72) Inventor: Nam Gyun KIM, Gwangju (KR)

(21) Appl. No.: 17/787,614

(22) PCT Filed: Feb. 23, 2021
(86) PCT No.: PCT/KR2021/002252

§ 371 Date: Jun. 21, 2022

(30) Foreign Application Priority Data
Feb. 25, 2020 (KR) 10-2020-0022808

(51) Int. Cl. H01F 17/04; B62D 5/04; H02M 1/00; H01F 1/34

(52) U.S. Cl. CPC H01F 17/045; B62D 5/046; B62D 5/0481; H02M 1/0064; H01F 1/34

(57) ABSTRACT

The present embodiments relate to an inductor device, a filter device and a steering assist device. The inductor device can comprise: a core including a magnetic material; and a wire which is wound around the core and which includes a low resistance material.

### TECHNICAL FIELD

The present embodiments relate to an inductor device, a filter device and a steering control device.

### BACKGROUND ART

In general, steering system refers to a system in which the driver of a vehicle may change the steering angle of the wheels of a vehicle based on the steering force (or rotational force) applied to the steering wheel. Electromotive power steering systems, e.g., electric power steer (EPS), have been recently applied to vehicles to ensure stable steering by reducing the steering force of the steering wheel.

To enhance the performance of the steering system, it is necessary to study a method for reducing electric noise included in a current flowing through a power line and a method for measuring a current flowing through the power line in the steering system.

### DETAILED DESCRIPTION OF THE INVENTION

### Technical Problem

The present embodiments may provide an inductor device capable of not only filtering noise included in current, but also enabling current sensing.

Further, the present embodiments may provide a filter device capable of not only filtering noise included in the current but also sensing the current.

Further, the present embodiments may provide a steering control device capable of not only filtering noise included in current and sensing the current to control the steering assist.

### Technical Solution

In an aspect, the present embodiments may provide an inductor device comprising a core including a magnetic material; and a wire wound on the core and including a shunt resistor including a low-resistance material.

In another aspect, the present embodiments may provide a filter device including an inductor unit to filter noise included in current and sense the current, wherein the inductor unit includes a core including a magnetic material; and a wire wound on the core and including a shunt resistor including a low-resistance material.

In another aspect, the present embodiments may provide a steering control device comprising a filter unit including an inductor unit to filter noise included in current and sense the current; and a steering motor power source unit generating an assist current by converting the filtered current based on a steering motor control signal and controlling a steering motor based on the assist current, wherein the inductor unit includes a core including a magnetic material; and a wire wound on the core and including a shunt resistor including a low-resistance material.

### Advantageous Effects

According to the present embodiments, there may be provided an inductor device capable of not only filtering noise included in current, but also enabling current sensing.

According to the present embodiments, there may be provided a filter device capable of not only filtering noise included in the current but also sensing the current.

According to the present embodiments, there may be provided a steering control device capable of not only filtering noise included in current and sensing the current to control the steering assist.

### BRIEF DESCRIPTION OF DRAWINGS

FIG. 1 is a block diagram illustrating a configuration of an inductor device according to the present embodiments;

FIGS. 2 to 5 are views illustrating an inductor device according to the present embodiments;

FIG. 6 is a block diagram illustrating a configuration of a filter device according to the present embodiments;

FIGS. 7 and 8 are circuit diagrams illustrating a form of a filter device according to the present embodiments;

FIG. 9 is a block diagram illustrating a configuration of a steering control device according to the present embodiments; and

FIG. 10 is a block diagram illustrating a configuration of a steering system according to the present embodiments.

### MODE FOR CARRYING OUT THE INVENTION

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description may make the subject matter in some embodiments of the present disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

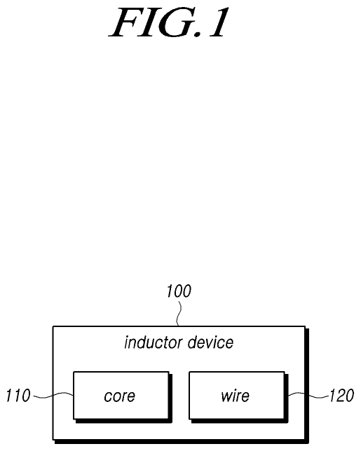

FIG. 1 is a block diagram illustrating a configuration of an inductor device according to the present embodiments.

Referring to FIG. 1, an inductor device 100 according to the present embodiments may include at least one of a core 110 and a wire 120. The core 110 and the wire 120 may be connected electrically, magnetically, or mechanically.

According to embodiments, the inductor device 100 may include a core 110 including a magnetic material and a wire 120 wound around the core 110 and including a low-resistance material.

Specifically, the core 110 may form a body. In other words, the core 110 may form a body so that the wire 120 may be wound therearound

The core 110 may include a magnetic material.

Here, the magnetic material may include a ferrite material, but is not limited thereto, and may include any material as long as it has magnetism.

In particular, the ferrite material may include at least one of a nickel-zinc (Ni—Zn)-based ferrite material and a manganese-zinc (Mn—Zn)-based ferrite material, but without limitations thereto, may include any ferrite material as long as it has magnetism.

The core 110 may include at least one of a circular shape (e.g., a cylindrical shape, a drum shape, and/or a cylindrical shape) and a polygonal shape (e.g., a polyhedral shape, etc.), but without limitations thereto, may have any shape capable of forming a body around which the wire 120 may be wound.

The wire 120 may be wound on the core 110. If a current flows through the wire 120 wound around the core 110, the wire 120 wound around the core 110 may generate an electromagnetic field.

The wire 120 may include a low-resistance material.

Here, the low-resistance material may refer to a material capable of not only forming an inductance together with the magnetic material of the core 110 but also enabling current sensing.

Here, the low-resistance material may have a resistance value within a preset resistance value.

In particular, the preset resistance value may be a maximum resistance value capable of current sensing.

For example, the wire 120 may include a shunt resistor including a low-resistance material, but without limitations thereto, may include any resistor as long as it has a resistance value within the preset resistance value to enable current sensing.

Here, the low-resistance material may include a copper alloy material, but without limitations thereto, may include any material as long as it has a resistance value within the preset resistance value to enable current sensing.

For example, the low-resistance material may include at least one alloy material among a copper-manganese (Cu—Mn) alloy material, a copper-nickel (Cu—Ni) alloy material, an iron-chromium (Fe—Cr) alloy material, and an iron-nickel (Fe—Ni) alloy material, but without limitations thereto, may include any material as long as it has a resistance value within the preset resistance value to enable current sensing.

According to the foregoing description, according to embodiments, the inductor device 100 may include a core 110 including a magnetic material; and a wire 120 wound on the core 110 and including a shunt resistor including a low-resistance material. The magnetic material may include a ferrite material. The low-resistance material may include at least one alloy material among a copper-manganese (Cu—Mn) alloy material, a copper-nickel (Cu—Ni) alloy material, an iron-chromium (Fe—Cr) alloy material, and an iron-nickel (Fe—Ni) alloy material.

Thus, as compared with the conventional inductor having only a copper wire and capable of only filtering the noise included in current, the inductor device according to the present embodiments may provide an inductor that may not only filter the noise included in current but also enable current sensing, i.e., multi-functional inductor, by forming an inductance through the low-resistance material included in the wire (e.g., the shunt resistor) and the magnetic material included in the core.

Meanwhile, the above-described current may have equivalent meanings to terms, such as electric energy, electric signal, voltage, and the like.

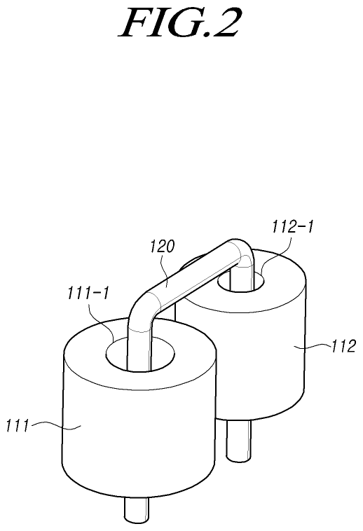

FIGS. 2 to 5 are views illustrating an inductor device according to the present embodiments.

Referring to FIG. 2, there may be two cores 110 but, without limitations thereto, one or three or more cores may be provided. Hereinafter, for the sake of brevity of description, a case in which there are two cores is described.

The cores 110 may include a first core 111 and a second core 112. As shown in the drawings, the first core 111 and the second core 112 may have a drum shape, but without limitations thereto, changes may be made thereto.

The first core 111 may include a first hole 111-1. In other words, the first core 111 may include a first hole 111-1 through which the wire 120 passes. The second core 112 may include a second hole 112-1. In other words, the second core 112 may include a second hole 112-1 through which the wire 120 passes.

Here, the first hole 111-1 and the second hole 112-1 may have a single cylindrical shape as shown in the drawings, but without limitations thereto, may have a plurality of cylindrical shapes. In other words, modifications may be made to the shape and number of the first hole 111-1 and the second hole 112-1.

The wire 120 may pass through the first hole 111-1 included in the drum-shaped first core 111 and the second hole 112-1 included in the drum-shaped second core 112. In other words, the wire 120 may pass through the first hole 111-1 included in the drum-shaped first core 111 and the second hole 112-1 included in the drum-shaped second core 112 and be then wound around the first core 111 and the second core 112.

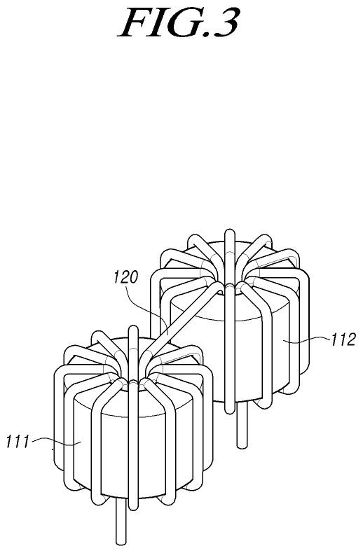

Referring to FIG. 3, the wire 120 passing through the first hole 111-1 of the first core 111 may be wound by a first number of turns. Further, the wire 120 passing through the second hole 112-1 of the second core 112 may be wound by a second number of turns.

Here, the first and second numbers of turns may have a proportional relationship with the inductance.

Here, the first and second numbers of turns may have the same value, but without limitations thereto, may have different values.

In particular, as the number of turns increases, the inductance may increase and impedance is increased accordingly. The inductor according to the present embodiments may reduce the noise included in the current by adjusting the frequency therethrough. Accordingly, the inductor device according to the present embodiments may enhance the performance of removing the noise included in the current by adding turns of the wire.

Meanwhile, even when the first and second numbers of turns are increased, the first and second numbers of turns may be increased by a range in which the wire 120 having the low-resistance material may sense the current.

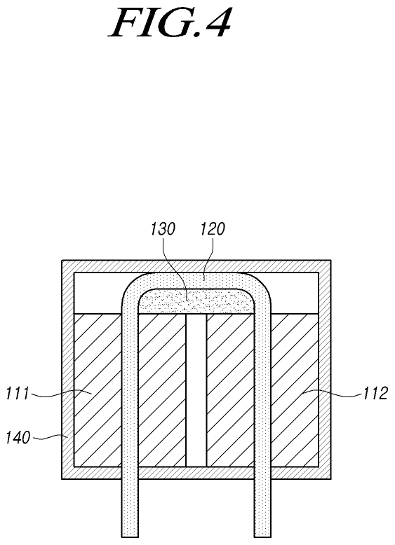

Referring to FIG. 4, the inductor device 100 according to embodiments may further include at least one of an adhesive 130 and a case 140.

The adhesive 130 may be positioned between the core 110 and the wire 120. The adhesive 130 may fix the core 110 and the wire 120. In other words, the adhesive 130 may be positioned between the upper surfaces of the first core 111 and the second core 112 and the wire 120 as shown in the drawings.

The adhesive 130 is a portion having a function of fixing the core 110 and the wire 120, and is not limited by the term. In other words, the adhesive 130 may include any structure, method, and material capable of fixing the core and the wire.

The case 140 may be a space in which the core 110, the wire 120, and the adhesive 130 are placed. The shape of the case shown in the drawings is merely an embodiment, and may have any shape where the wire, and adhesive may be placed.

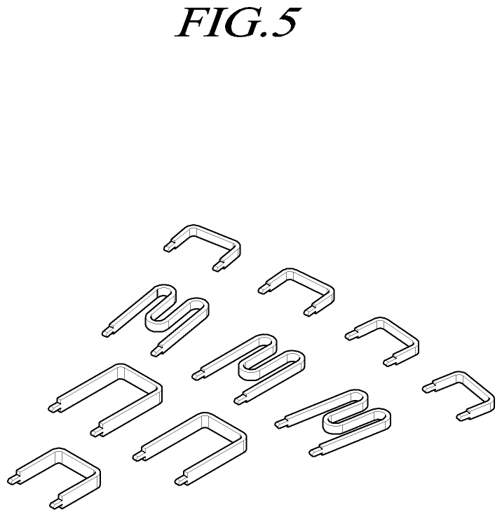

Referring to FIG. 5, the shunt resistor may be wound through the first hole 111-1 of the first core 111 and the second hole 112-1 of the second core 112. The shape of the shunt resistor shown in the drawing is merely an example, and may have any shape that may pass through the first hole 111-1 of the first core 111 and the second hole 112-1 of the second core 112 and be wound.

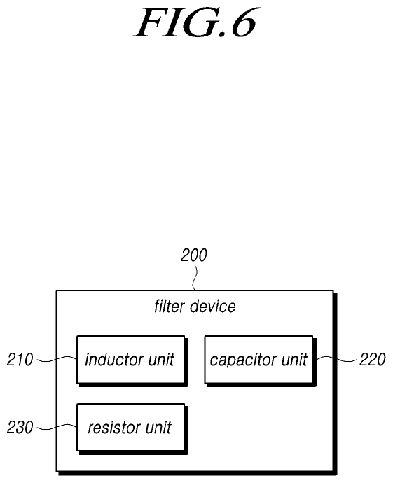

FIG. 6 is a block diagram illustrating a configuration of a filter device according to the present embodiments.

Referring to FIG. 6, a filter device 200 according to embodiments may include an inductor unit 210 to filter noise included in current and sense current. The inductor unit 210 may include a core including a magnetic material and a wire wound around the core and including a low-resistance material.

Here, the magnetic material may include a ferrite material.

Here, the wire may include a shunt resistor including a low-resistance material.

Here, the low-resistance material may include at least one alloy material among a copper-manganese (Cu—Mn) alloy material, a copper-nickel (Cu—Ni) alloy material, an iron-chromium (Fe—Cr) alloy material, and an iron-nickel (Fe—Ni) alloy material.

Meanwhile, the inductor unit 210 may be understood as the same component as the inductor device 100 described above in connection with FIGS. 1 to 5, that is, all functions of the inductor device 100 may be applied. Thus, for the sake of simplicity, a description overlapping the inductor device 100 is omitted below.

Further, the filter device 200 according to embodiments may further include at least one of a capacitor unit 220 and a resistor unit 230.

At least one of the capacitor unit 220 and the resistor unit 230 may be connected to the inductor unit 210 to constitute a filter.

Meanwhile, the inductor unit 210 may include (or mean) an inductor, and there may be one or more inductor units. The capacitor unit 220 may include (or mean) a capacitor, and there may be one or more capacitor units. The resistor unit 230 may include (or mean) a resistor, and there may be one or more resistor units.

Meanwhile, the filter device 200 according to embodiments may include at least one filter among an L filter, an LC filter, an RL filter, and an RLC filter, but without limitations thereto, may include any filter that is formed to include at least one of the inductor unit 210, the capacitor unit 220, and the resistor unit 230.

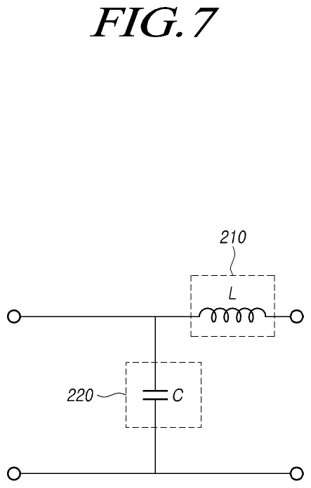

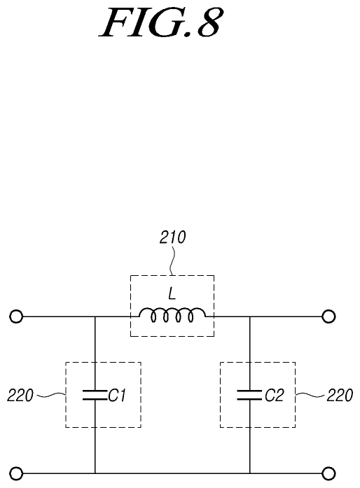

FIGS. 7 and 8 are circuit diagrams illustrating a form of a filter device according to the present embodiments.

Referring to FIG. 7, the filter device 200 according to embodiments may include an inductor unit 210 and a capacitor unit 220. The inductor unit 210 may include an inductor L. The capacitor unit 220 may include a capacitor C. In other words, the filter device according to embodiments may be an LC filter.

Thus, the filter device 200 including the LC filter according to the present embodiments may filter current through the inductor L and the capacitor C while simultaneously sensing current through the inductor.

Referring to FIG. 8, the filter device 200 according to embodiments may include an inductor unit 210 and a capacitor unit 220. The inductor unit 210 may include an inductor L. The capacitor unit 220 may include a first capacitor C1 and a second capacitor C2. In other words, the filter device 200 according to the present embodiments may be a n-shaped LC filter.

Accordingly, the filter device 200 including the n-shaped LC filter according to the present embodiments may filter the current through the inductor L and the first and second capacitors C1 and C2 while simultaneously sensing current through the inductor.

Thus, as compared with the conventional power line filter which requires addition of a circuit component and an additional PCB space for adding a separate hall sensor for current sensing to measure current consumption, the filter device according to the present embodiments includes an inductor having a form in which a wire (e.g., shunt resistor) including a low-resistance material is wound around a core including a magnetic material and filters noise included in current while simultaneously sensing current. As such, the filter device according to the present embodiments allows for two functions, e.g., power filter and current consumption measurement, with one component, thus reducing circuit components and the PCB space.

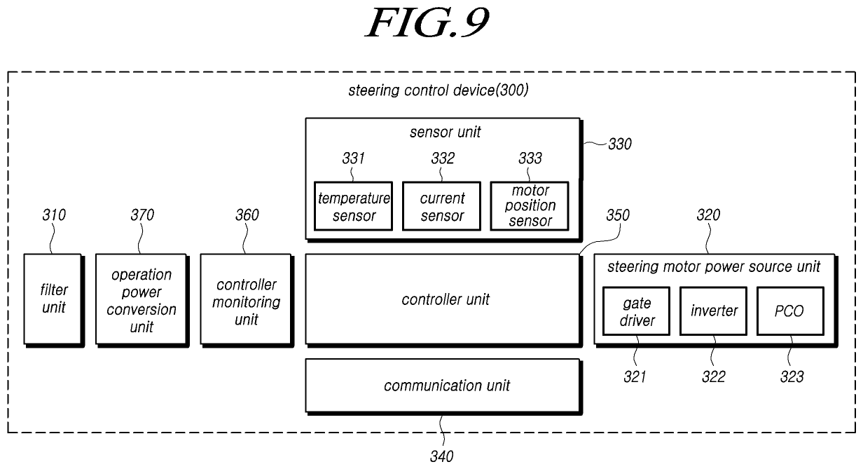

FIG. 9 is a block diagram illustrating a configuration of a steering control device according to the present embodiments.

Referring to FIG. 9, a steering control device 300 according to the present embodiments may include at least one of a filter unit 310, a steering motor power source unit 320, a sensor unit 330, a communication unit 340, a controller unit 350, a controller monitoring unit 360, and an operation power conversion unit 370.

The filter unit 310 may be connected to the input power source. The filter unit 310 may filter noise of electric energy provided from the input power source and provide the filtered electric energy to the steering motor power source unit 320 and the operation power conversion unit 370. The steering motor power source unit 320 may be connected with the filter unit 310 and receive filtered electric energy. The steering motor power source unit 320 may be connected with the controller unit 50 and may receive a steering motor control signal. The steering motor power source unit 320 may generate an assist steering force by converting the filtered electric energy based on the steering motor control signal, and control the steering motor based on the assist steering force.

The steering motor power source unit 320 may include a gate driver 321, an inverter 322, and a phase disconnector (PCO) 323.

The gate driver 321 may receive the steering motor control signal from the controller unit 350, generate a gate signal based on the steering motor control signal, and provide the gate signal to the inverter 322. The inverter 322 may convert the filtered electric energy of the filter unit according to the gate signal, generating an assist steering force. The phase disconnector (e.g., a breaker or a disconnecting switch) 323 is positioned between the inverter 322 and the steering motor and may supply or cut off the assist steering force provided from the inverter 322 to the steering motor.

The sensor unit 330 may include at least one of a temperature sensor 331, a current sensor 332, or a motor position sensor 333 but, without limitations thereto, may include any sensor that may measure the state of the steering system (or the steering control device).

The temperature sensor 331 may measure the temperature of the steering control device 300 and provide the temperature information to the controller unit 350. Further, the current sensor 332 may measure the assist current (or assist steering force) provided from the steering motor power source unit 320 to the steering motor and provide the assist current information to the controller unit 350. The motor position sensor 333 may measure the position of the steering motor and provide the position information about the steering motor to the controller unit 350.

The communication unit 340 may include at least one of an internal communication unit or an external communication unit. When there are a plurality of steering control devices, the internal communication unit may be connected with other steering control devices to receive or provide information. The external communication unit may be connected with the vehicle to receive vehicle state information (e.g., vehicle speed information) from the vehicle or provide information related to the steering system to the vehicle.

The controller unit 350 may be connected to each component of the steering control device to provide information or receive information to control the operation.

For example, the controller unit 350 may generate a steering motor control signal based on at least one of the torque information about the steering wheel, steering angle information about the steering wheel, temperature information, assist current information, position information about the steering motor, vehicle state information (e.g., vehicle speed information), state information about the input power source, short circuit (or overcurrent) state information, current sensing information about the filter unit, or state information about the steering motor, and provide the steering motor control signal to the gate driver, or may generate a separation/connection control signal (e.g., a clutch control signal) and provide the separation/connection control signal to the separation/connection mechanism.

The controller unit 350 may include a microcontroller but, without limitations thereto, may include any device (or computer) that may process (or execute or compute) programs.

The controller unit 350 may include at least one or more of one or more processors, a memory, a storage unit, a user interface input unit, or a user interface output unit which may communicate with one another via a bus. The controller unit 350 may also include a network interface for accessing a network. The processor may be a central processing unit (CPU) or semiconductor device that executes processing instructions stored in the memory and/or the storage unit. The memory and the storage unit may include various types of volatile/non-volatile storage media. For example, the memory may include a read only memory (ROM) and a random access memory (RAM). Here, the producer 120 may include at least one core. In particular, if the at least one core includes a plurality of cores, at least one of the plurality of cores may include a lockstep core.

The controller monitoring unit 360 may be connected with the controller unit 350. The controller monitoring unit 360 may monitor the operating state of the controller unit 350. For example, the controller unit 350 may provide a watchdog signal to the controller monitoring unit 360. The controller monitoring unit 360 may be cleared based on the watchdog signal received from the controller unit 350 or may generate a reset signal and provide the reset signal to the controller unit 350.

The controller monitoring unit 360 may include a watchdog but, without limitations thereto, may include any device capable of monitoring the controller unit. In particular, a watchdog may include a window watchdog having a deadline, that is, a start and an end.

The operation power conversion unit 370 may be connected with the filter unit 310. The operation power conversion unit 370 may generate an operating voltage for each component of the steering control device 300 by converting the filtered electric energy of the filter unit 310. The operation power conversion unit 370 may include at least one of a DC-DC converter or a regulator but, without limitations thereto, may include any device that may convert the output from the power protection module to thereby generate an operating voltage for each component of the steering control device. Meanwhile, the steering control device 300 may include an electronic control unit (ECU) but, without limitations thereto, may include any control device (or system) that may perform electronic control.

Here, the electric energy may include an electric current.

Here, the assist steering force may include an assist current.

Meanwhile, the steering control device 300 may include a filter unit 310 including an inductor unit to filter noise included in current and sense the current; and a steering motor power source unit 320 generating an assist current by converting the current filtered based on a steering motor control signal and controlling a steering motor based on the assist current. The inductor unit may include a core including a magnetic material; and a wire wound on the core and including a low-resistance material.

Here, the magnetic material may include a ferrite material.

Here, the wire may include a shunt resistor including a low-resistance material.

Here, the low-resistance material may include at least one alloy material among a copper-manganese (Cu—Mn) alloy material, a copper-nickel (Cu—Ni) alloy material, an iron-chromium (Fe—Cr) alloy material, and an iron-nickel (Fe—Ni) alloy material.

Meanwhile, the filter unit 310 may be understood as the same component as the filter device 200 described above in connection with FIGS. 6 to 8, that is, all functions of the filter device 100 may be applied. Thus, for the sake of simplicity, a description overlapping the filter device 200 is omitted below.

Meanwhile, the controller unit 350 according to embodiments may generate a steering motor control signal The controller unit 350 may determine the state of the steering control device 300 based on the current sensed through the inductor unit and may control the steering motor power source unit 320 according to the determination result.

In other words, the controller unit 350 may compare the sensing current value corresponding to the current sensed through the inductor unit with a preset current value and may determine that the steering control device 300 is in a normal state if the sensing current value is determined to be the preset current value or less.

The controller 350 may generate a steering motor control signal corresponding to the normal state of the steering control device 300.

The steering motor power source unit 320 may generate an assist current by converting the filtered current based on the steering motor control signal corresponding to the normal state of the steering control device 300 and control the steering motor based on the assist current

Further, the controller unit 350 may compare the sensing current value corresponding to the current signal sensed through the inductor unit with a preset current value and may determine that the steering control device 300 is in an abnormal state if the sensing current value is determined to be more than the preset current value.

The controller 350 may generate a steering motor control signal corresponding to the abnormal state of the steering control device 300.

The steering motor power source unit 320 may stop the operation based on the steering motor control signal corresponding to the abnormal state of the steering control device 300 to stop the operation of the steering motor.

Here, the preset current value may be the maximum value of the input current value required when the steering control device 300 and the steering motor are normal. In particular, the input current value may be a current value between the input power source and the steering motor power source unit 320 (particularly, the inverter 322).

As described above, the steering control device according to the present embodiments may measure the current consumption at the power source end through the inductor including the core including the magnetic material and the wire (e.g., a shunt resistor) including the low-resistance material, determine the operation state of the steering control device and the steering system based on the measured current consumption, and control the operation of the steering control device and steering system according to the determination result, thereby increasing the reliability of the steering control device and the steering system.

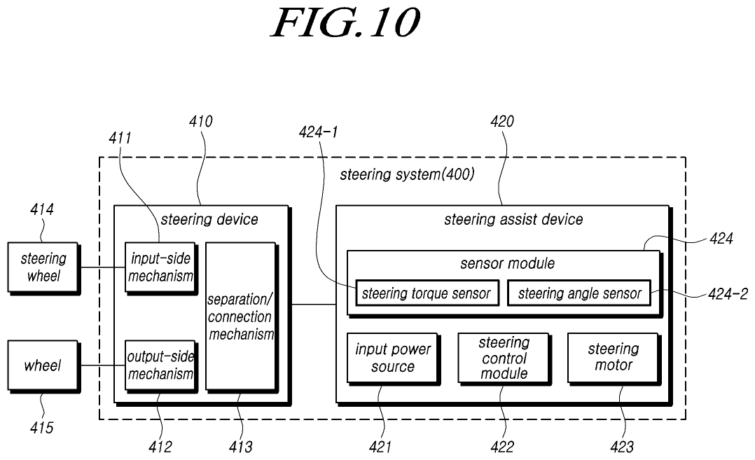

FIG. 10 is a block diagram illustrating a configuration of a steering system according to the present embodiments.

Referring to FIG. 10, a steering system 400 according to the present embodiments may include at least one of a steering device 410 or a steering assist device 420. The steering device 410 and the steering assist device 420 may be connected by at least one of an electrical, magnetic, or mechanical connection.

The steering device 410 may change the steering angle of a wheel 315 based on a steering force (or rotational force) applied to the steering wheel 414. The steering device 410 may include an input-side mechanism 411 and an output-side mechanism 412. Further, the steering device 410 may further include a separation/connection mechanism 413.

The input-side mechanism 411 may be connected to the steering wheel 314. The input-side mechanism 411 may rotate in a rotational direction of the steering wheel 414 or in a direction opposite to the rotational direction of the steering wheel 414. The input-side mechanism 411 may include a steering shaft connected to the steering wheel 414 but, without limitations thereto, may include any mechanism (or device) that may rotate in the rotational direction of the steering wheel or in the direction opposite to the rotational direction of the steering wheel.

The output-side device 412 may be connected to the input-side device 411 by at least one of an electrical or mechanical connection. The output-side mechanism 412 may be connected to the wheel 415, changing the steering angle (or movement) of the wheel 415. The output-side mechanism 412 may include at least one of a pinion, a rack, a tie rod, or a knuckle arm but, without limitations thereto, may include any mechanism (or device) that may change the steering angle (or movement) of the wheel.

The separation/connection mechanism 413 may be connected to the input-side mechanism 411 and the output-side mechanism 412. The separation/connection mechanism 413 may mechanically or electrically connect or separate the input-side mechanism 411 and the output-side mechanism 412. The separation/connection mechanism 413 may include a clutch but, without limitations thereto, may include any mechanism (or device) that may connect or separate the input-side mechanism and the output-side mechanism.

According to an embodiment, the steering device 410 may include at least one of a steering device in which an input-side mechanism and an output-side mechanism are connected mechanically, a steering device (or steer by wire (SbW)) in which an input-side mechanism and an output-side mechanism are connected electrically, or a steering device (or an SbW including a clutch) in which an input-side mechanism and an output-side mechanism are connected with a separation/connection mechanism.

Meanwhile, the steering wheel 414 and the wheel 415 are illustrated as not being included in the steering device 410 but, without limitations thereto, may be included in the steering device 400.

The steering assist device 420 may be connected with the steering device 410. The steering assist device 420 may provide an assist steering force to the steering device 410.

According to an embodiment, the steering assist device 420 may include at least one of an input power source 421, a steering control module 422, a steering motor 423, or a sensor module 424.

The input power source 421 may include at least one of a direct current (DC) power source or an alternating current (AC) power source. In particular, the DC power source may include a battery but, without limitations thereto, may include any power source may provide DC power.

The steering control module 422 may be connected to the input power source 421. The steering control module 422 may receive electric energy from the input power source 421, filter noise in the electric energy, generate an assist steering force by converting the filtered electric energy based on the steering motor control signal, and control the steering motor 423 based on the assist steering force.

The sensor module 424 may include at least one sensor.

Here, the sensor may include at least one of a steering torque sensor 424-1 and a steering angle sensor 424-2 but, without limitations thereto, may include any sensor capable of measuring the state of the vehicle and the steering state of the vehicle.

The steering torque sensor 424-1 may measure the steering torque of the steering wheel and provide the torque information about the steering wheel to the steering control module 422. Further, the steering angle sensor 424-2 may measure the steering angle of the steering wheel and provide steering angle information about the steering wheel to the steering control module 422.

The steering control module 422 may generate a steering motor control signal based on at least one piece of information among the steering torque information and steering angle information, generate an assist steering force by converting the filtered electric energy according to the steering motor control signal, and control the steering motor 423 based on the assist steering force.

The steering motor 423 may be connected with the steering control module 422. The steering motor 423 may operate based on the assist steering force provided from the steering control module 422, assisting the steering device 410 in steering.

The steering motor 423 may include at least one of a single winding-type motor or a dual winding-type motor but, without limitations thereto, may include any motor that may assist the steering device in steering.

The steering motor 423 may include at least one of a three-phase type motor, or a five-phase type motor but, without limitations thereto, may include any motor that may assist the steering device in steering.

Here, the electric energy may include an electric current.

Here, the assist steering force may include an assist current.

Meanwhile, the steering assist device 420 may include an input power source 421 providing current; and a steering control module 422 including a filter unit including an inductor unit to filter noise included in current and sense the current; and a steering motor power source unit 422 generating an assist current by converting the current filtered based on a steering motor control signal and controlling a steering motor based on the assist current. The inductor unit may include a core including a magnetic material; and a wire wound on the core and including a low-resistance material and may sense the current signal.

Here, the magnetic material may include a ferrite material.

Here, the wire may include a shunt resistor including a low-resistance material.

Here, the low-resistance material may include at least one alloy material among a copper-manganese (Cu—Mn) alloy material, a copper-nickel (Cu—Ni) alloy material, an iron-chromium (Fe—Cr) alloy material, and an iron-nickel (Fe—Ni) alloy material.

Meanwhile, the steering control module 422 may be understood as the same component as the steering control device 300 described above in connection with FIG. 9, that is, all functions of the steering control device 300 may be applied. Thus, for the sake of simplicity, a description overlapping the steering control device 300 is omitted below.

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the present disclosure. The above description and the accompanying drawings provide an example of the technical idea of the present disclosure for illustrative purposes only. That is, the disclosed embodiments are intended to illustrate the scope of the technical idea of the present disclosure. Thus, the scope of the present disclosure is not limited to the embodiments shown, but is to be accorded the widest scope consistent with the claims. The scope of protection of the present disclosure should be construed based on the following claims, and all technical ideas within the scope of equivalents thereof should be construed as being included within the scope of the present disclosure.

### CROSS-REFERENCE TO RELATED APPLICATION

This application claims priority to Korean Patent Application No. 10-2020-0022808 filed in the Korean Intellectual Property Office on Feb. 25, 2020, the disclosure of which is incorporated by reference herein in its entirety.

1. An inductor device, comprising:
a core including a magnetic material; and
a wire wound on the core and including a shunt resistor including a low-resistance material,
wherein the magnetic material includes a ferrite material, and
wherein the low-resistance material includes at least one alloy material among a copper-manganese (Cu—Mn) alloy material, a copper-nickel (Cu—Ni) alloy material, an iron-chromium (Fe—Cr) alloy material, and an iron-nickel (Fe—Ni) alloy material.

2. The inductor device of claim 1, wherein the core includes,
a first core including a first hole; and
a second core including a second hole,
wherein the first core and the second core have a drum shape, and
wherein the wire passes through the first hole included in the drum-shaped first core and the second hole included in the drum-shaped second core.

3. The inductor device of claim 1, further comprising an adhesive fixing the core and the wire.

4. A filter device including an inductor unit to filter noise included in current and sense the current,
wherein the inductor unit includes,
a core including a magnetic material; and
a wire wound on the core and including a shunt resistor including a low-resistance material,
wherein the magnetic material includes a ferrite material, and
wherein the low-resistance material includes at least one alloy material among a copper-manganese (Cu—Mn) alloy material, a copper-nickel (Cu—Ni) alloy material, an iron-chromium (Fe—Cr) alloy material, and an iron-nickel (Fe—Ni) alloy material.

5. The filter device of claim 4, wherein the core includes,
a first core including a first hole; and
a second core including a second hole,
wherein the first core and the second core have a drum shape, and
wherein the wire passes through the first hole included in the drum-shaped first core and the second hole included in the drum-shaped second core.

6. The filter device of claim 4, wherein the inductor unit further includes an adhesive fixing the core and the wire.

7. The filter device of claim 4, further comprising a capacitor unit connected with the inductor unit,
wherein the inductor unit and the capacitor unit are a Π-shaped LC filter.

8. A steering control device, comprising:
a filter unit including an inductor unit to filter noise included in current and sense the current; and
a steering motor power source unit generating an assist current by converting the filtered current based on a steering motor control signal and controlling a steering motor based on the assist current,
wherein the inductor unit includes,
a core including a magnetic material; and
a wire wound on the core and including a shunt resistor including a low-resistance material,
wherein the magnetic material includes a ferrite material, and
wherein the low-resistance material includes at least one alloy material among a copper-manganese (Cu—Mn) alloy material, a copper-nickel (Cu—Ni) alloy material, an iron-chromium (Fe—Cr) alloy material, and an iron-nickel (Fe—Ni) alloy material.

9. The steering control device of claim 8, wherein the core includes,
a first core including a first hole; and
a second core including a second hole,
wherein the first core and the second core have a drum shape, and
wherein the wire passes through the first hole included in the drum-shaped first core and the second hole included in the drum-shaped second core.

10. The steering control device of claim 8, further comprising a capacitor unit connected with the inductor unit,
wherein the inductor unit and the capacitor unit are a n-shaped LC filter.

11. The steering control device of claim 8, further comprising a controller unit generating the steering motor control signal,
wherein the controller unit determines a state of the steering control device based on the current sensed through the inductor unit and controls the steering motor power source unit according to a result of the determination.
